(19) United States
(12) Patent Application Publication
(10) Pub. No.: US 2010/0006140 A1
(43) Pub. Date: Jan. 14, 2010

(54) Solar Energy System

(76) Inventors: James L. Parker, Reno, NV (US); Richard S. Kelsey, Sparks, NV (US)

Correspondence Address: IAN F. BURNS & ASSOCIATES, 4790 Caughlin Parkway #701, RENO, NV, 89519-0907, US

(21) Appl. No.: 12/502,612

(22) Filed: Jul. 14, 2009

Related U.S. Application Data
(60) Provisional application No. 61/080,374, filed on Jul. 14, 2008.

(51) Int. Cl. H01L 31/052

(52) U.S. Cl. 136/246

(57) ABSTRACT

A solar covering is disclosed that comprises a lens array configured to distribute light incident on the covering to solar receptors beneath the covering. The lens array may have a support structure covered by a continuous plastic sheet with Fresnel lens ribs or circular Fresnel elements or the lens array may comprise a number of Fresnel tiles. Each lens may concentrate light onto a solar receptor, such as a photovoltaic chip. The solar covering may go over new or existing photovoltaic panels such as on a solar cabana. A photovoltaic element may be movable to maintain the element in a concentration zone of a Fresnel lens and/or to control the power output of the photovoltaic element, such as in response to a signal from a power utility.

### CROSS REFERENCE TO RELATED APPLICATIONS

This application claims priority to U.S. provisional patent application Ser. No. 61/080,374, filed Jul. 14, 2009, the contents of which is herein incorporated by reference.

### FIELD OF THE INVENTION

The present invention relates to solar energy generation systems and in particular to photovoltaic systems.

### BACKGROUND

Solar energy systems are widely used for converting solar energy into other useful forms of energy, such as electrical energy in a photovoltaic cell or thermal energy, such as in a solar hot water system.

In a typical photovoltaic system, a collector panel of photovoltaic cells is provided in a path of sunlight. Sunlight impinging on the photovoltaic cell is converted to electrical energy and used to charge a battery. The amount of electricity generated by the photovoltaic cell is dependent on the amount of sunlight that impinges on the cell. Sunlight tracking systems may be used for changing the orientation of the photovoltaic cell during the day as the sun moves across the sky and during the seasons to track the sun, known as “sun-flowering” and therefore maximize the amount of sunlight that the photovoltaic cell receives. However, such tracking systems not only have an infrastructure cost, but also an energy cost, and careful consideration needs to be made to determine whether the energy gain created by tracking the sun more closely is worth the energy requirements for moving the solar panels.

What is required is an improved system and method for increasing the efficiency of a solar collector.

### SUMMARY OF ONE EMBODIMENT OF THE INVENTION

### Advantages of One or More Embodiments of the Present Invention

The various embodiments of the present invention may, but do not necessarily, achieve one or more of the following advantages:

the ability to increase the amount of solar energy absorber by a solar panel; and

provide increased solar energy absorption for an existing installation of solar panels;

provide the ability to integrate a vehicle shelter with a solar energy system;

provide a moveable array of smaller solar energy collectors;

provide a network of solar energy collectors; and

provide tuning of a solar energy system depending on demand.

These and other advantages may be realized by reference to the remaining portions of the specification, claims, and abstract.

### Brief Description of One Embodiment of the Present Invention

The above description sets forth, rather broadly, a summary of one embodiment of the present invention so that the detailed description that follows may be better understood and contributions of the present invention to the art may be better appreciated. Some of the embodiments of the present invention may not include all of the features or characteristics listed in the above summary. There are, of course, additional features of the invention that will be described below and will form the subject matter of claims. In this respect, before explaining at least one preferred embodiment of the invention in detail, it is to be understood that the invention is not limited in its application to the details of the construction and to the arrangement of the components set forth in the following description or as illustrated in the drawings. The invention is capable of other embodiments and of being practiced and carried out in various ways. Also, it is to be understood that the phraseology and terminology employed herein are for the purpose of description and should not be regarded as limiting.

In one aspect, the invention relates to a solar panel cover that may be installed over a solar receptor system. The solar panel cover comprises a support structure that supports a plurality of lens elements. The lens elements may be configured to distribute light incident upon the cover to one or more solar receiving elements disposed beneath the cover.

In one aspect, the invention relates to a solar collector system comprising one or more solar receiving objects and a cover supported over the one or more solar receiving objects. The cover may include one or more lens elements that distribute light incident upon the cover to the one or more solar receiving elements.

In one aspect, the invention relates to a solar cabana having a framework that supports a roof. A solar power system may be supported on the roof. The solar power system may include one or more photovoltaic elements covered by a cover. The cover may include one or more lens elements that are configured to distribute light incident upon the cover to the one or more photovoltaic elements.

In one aspect, the invention relates to a kit for a solar cabana, the kit may include a roof, a framework and a solar power system. The framework may be configured, once constructed, to support the roof which may in turn support the solar power system. The solar power system may include a solar power system support structure that may be supported by the roof, a plurality of lens elements that may be supported on the solar power system support structure, and one or more photovoltaic elements.

### BRIEF DESCRIPTION OF THE DRAWINGS

FIG. 1 substantially shows a solar canopy of one embodiment of the present invention;

FIG. 2 substantially shows a solar canopy of an alternative embodiment;

FIG. 3 substantially shows an alternative lens array;

FIG. 4 substantially shows a light path through a lens array;

FIG. 5 substantially shows a lens array aligned with an inner photovoltaic array;

FIG. 6 substantially shows a light path through a Fresnel lens onto a solar absorber element;

FIG. 7 substantially shows a mechanism for moving a photovoltaic element;

FIG. 8 substantially shows a cabana having a solar canopy;

FIG. 9 substantially shows a lens element also having a holographic element;

FIG. 10 substantially shows the holographic element of FIG. 9;

FIG. 11 substantially shows an alternative solar collector;

FIG. 12 substantially shows a lens array network;

FIG. 13 substantially shows a lens array with sensor; and

FIG. 14 substantially shows a lens array network connected to a power grid.

### DESCRIPTION OF CERTAIN EMBODIMENTS OF THE PRESENT INVENTION

In the following detailed description of the preferred embodiments, reference is made to the accompanying drawings, which form a part of this application. The drawings show, by way of illustration, specific embodiments in which the invention may be practiced. It is to be understood that other embodiments may be utilized and structural changes may be made without departing from the scope of the present invention.

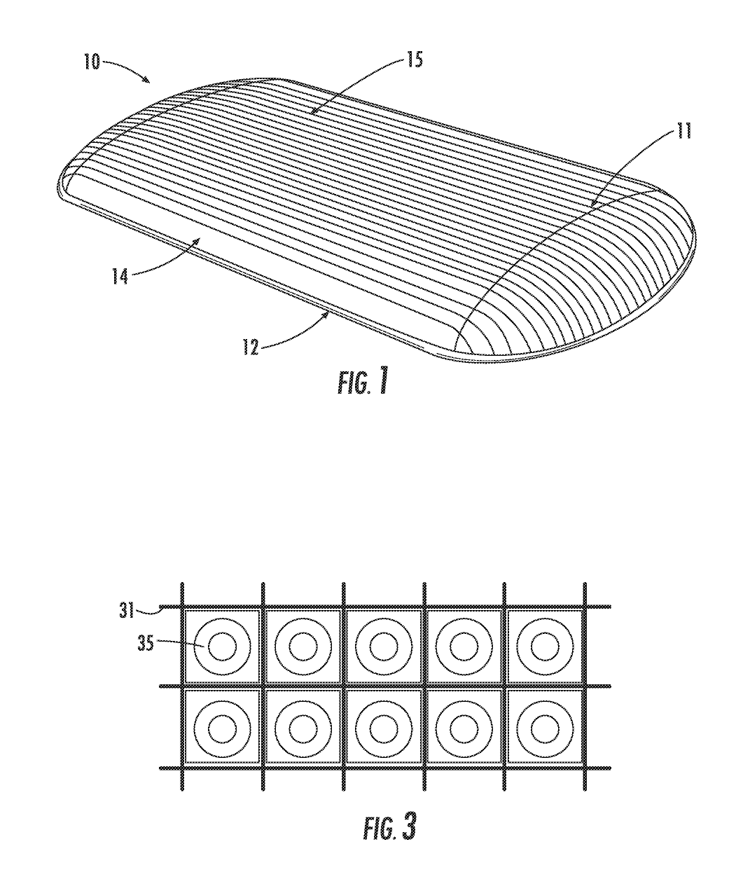

In one aspect of the invention, a solar covering is provided that combines optical and geometric properties to create a solar collector system that can significantly increase solar generation of DC (direct current) power. An example solar covering is shown generally at 10 in FIG. 1, and may include a support structure 11 that supports a plurality of lens elements 15. In one embodiment, the support structure 11 includes an arch support structure disposed over a solar receiving object 12, such as a photovoltaic cell or other solar absorber.

In one embodiment, the lens elements 15 are provided in a plastic overlay 14 that stretches over the support structure 11. The lens elements 15 may be Fresnel lenses provided as a plurality of extruded linear ribs. The ribbed Fresnel lens can include a plurality of Fresnel lens segments that provide a number of concentration zones beneath the covering. In one embodiment, the ribbed extrusion of the Fresnel lens may have an interconnect structure that allows multiple lenses to be joined, e.g. to make commercial grade systems many yards long.

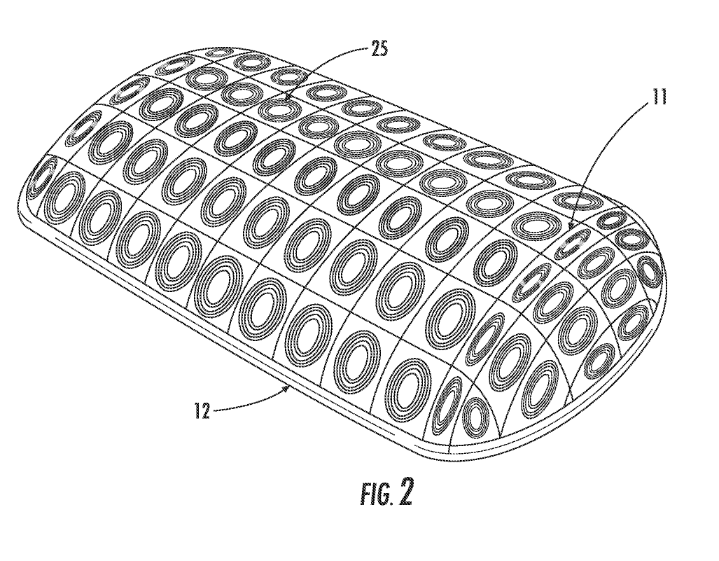

An alternative embodiment of the lens array, depicted in FIG. 2, has a plurality of circular lens elements 25, e.g. Fresnel lenses, embossed in the plastic sheet 14. In one embodiment, each circular Fresnel element may exist within a square of 4 inches to about 12 inches. Other Fresnel geometries may be apparent to a person skilled in the art as may other lens types.

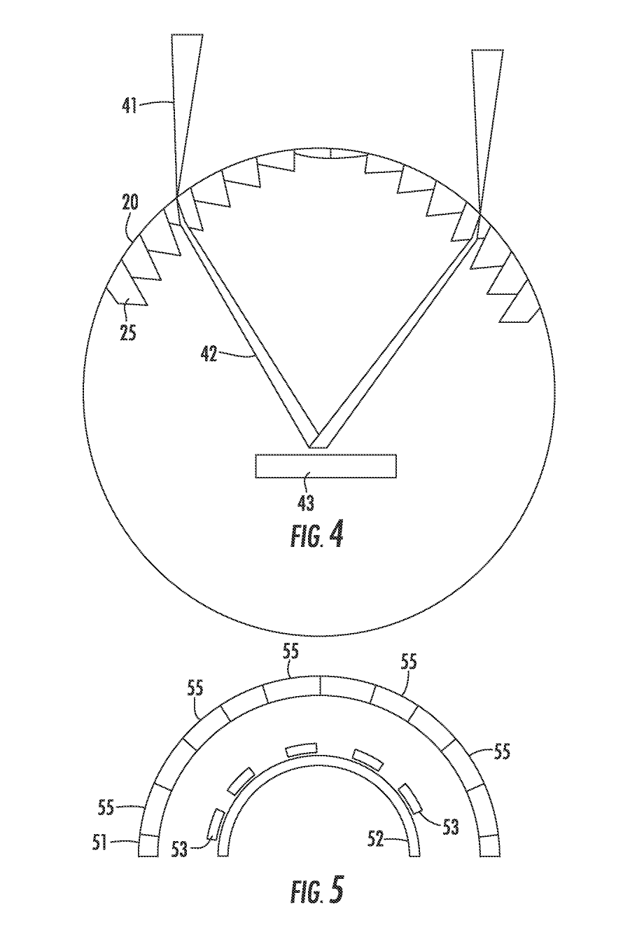

An alternative lens array 30 is shown in FIG. 3. In this embodiment, the support structure is provided as a lattice framework 31 that supports individual lens elements 35, such as a plurality of Fresnel lens tiles. While the lattice framework 31 is depicted in FIG. 3 as being relatively flat, the framework may have any suitable geometry including the arched geometry depicted in FIGS. 1 and 2. Similarly, the lens elements 35 may have any suitable geometry as required. The lens elements 35, e.g. Fresnel lens elements, may be formed in a relatively cheap material such as plastic.

In each of the above embodiments, the lens array is configured to capture sunlight that is incident upon the lens array and to distribute the light onto a receiving object disposed beneath the solar covering. The lens array with multiple lens elements may be designed to be a concentrator which collects solar flux from a wide area of incident radiation and over a large angle of light. The curved arch of the solar covering allows light concentration independent of the sun position. This flux is concentrated without energy loss into the smaller area of the receiving element surface beneath the lens array.

FIG. 4 shows the typical path of sunlight 41 at noon from directly overhead through the solar covering 20 of FIG. 2. Each lens element 25 concentrates the light 42 into a concentration zone at the absorber material 43. In one embodiment, the lenses 25 are designed to be non-imaging in the concentration zone, i.e. at the plane of the absorber material 43. That is, the solar covering uses multiple lens images to smooth the sun's flux through its daily travel so that the flux density applied to the photovoltaic is greater than without this artificial simulation of “sun-flowering”. Because the incoming light is not centered on the axis of the lens and because the lens array is curved, the resulting image will not be a point focused image, but will be distributed over the surface of the absorber plate 43. Sunlight at other times of the day will also be refracted onto the photovoltaic absorber plate evenly. Annual variations in sun position may be smoothed by the same method, without introducing the need for a two-axis rotation mechanism to track the sun.

In one embodiment, the continuous sheet may be flexible enough to wrap around a six inch radius. The thickness of the sheet may range from between about ⅛ inch and about ¼ inch depending on the application.

In one embodiment, the receiving object may be a photovoltaic element that provides electrical power either directly to a load circuit or into battery storage. Batteries, e.g. lithium ion batteries or other appropriate batteries, may be electrically coupled to the receiving photovoltaic absorber sheet 12. Alternatively, the receiving object may be any other type of solar absorber that can be used for converting sunlight energy into other forms of energy such as heat for a hot water system or other power generation means.

The solar covering canopy may be installed over existing photovoltaic installations to increase the electricity yield of panels already in place. A solar canopy over existing photovoltaic panels will increase the effective sun exposure capture area because the canopy will be wider than the existing panel as well as make the installation less sensitive to the daily changes in sun angle. The orientation of the photovoltaic panel with respect to east-west compass directions and the annual changes in sun path due to latitude will also not effect electricity yield. The curved lens array captures sunlight from sunup to sundown because each lens element in the sheet acquires light from all sun angles. A repeated design of Fresnel lenses across the solar covering can also capture the approximate 15% of diffuse sunlight that is present during a normal cloudless day. In cloudy conditions, the percentage of diffused light is higher, making the solar covering comparatively more efficient relative to an uncovered photovoltaic element.

The solar canopy has an additional advantage that the plastic web of the solar covering can protect the expensive glass photovoltaic panels from dirt and abrasion. Because the image created by the lens array is intentionally not focused, dirt accumulated on the solar covering will not cause performance deterioration in the lens system.

A typical existing installation might use a photovoltaic panel that is, for example, 8 feet wide. However, using a solar covering having a lens array as described above, the photovoltaic size may be reduced in size and correspondingly, reduced in cost. In one embodiment, 20 inch photovoltaic panels may be used.

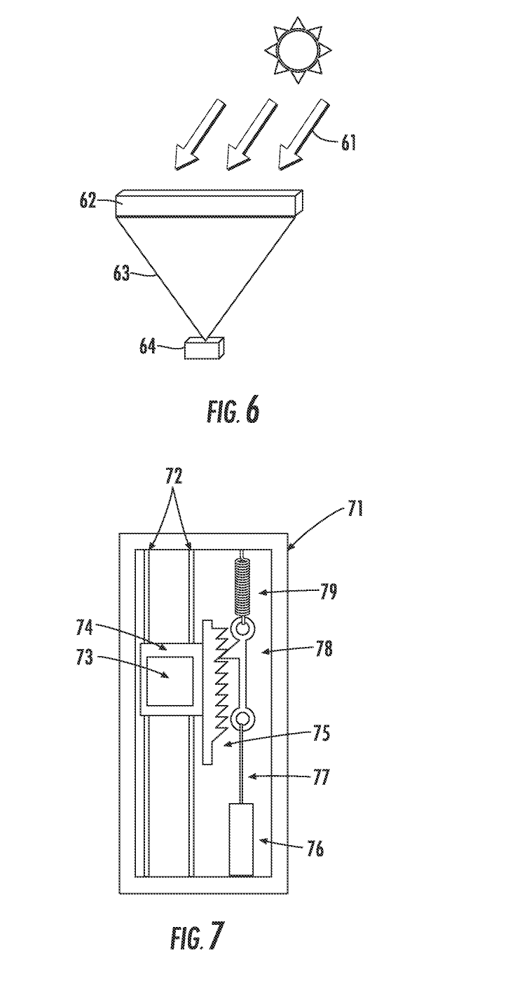

In an alternative embodiment, shown in FIG. 5, an array of photovoltaic chips 53 may be deployed on an internal framework 52 beneath the solar canopy 51. The photovoltaic chips 53 may be aligned with the concentration zones of the lens elements 55 of the canopy 51. Other forms of photovoltaic elements may be used in place of the photovoltaic chips 53.

Solar panels are more efficient at higher flux densities and therefore, by concentrating the sunlight, the same amount of electricity can be generated for a significantly reduced capital cost in photovoltaic panels.

As described above, sun tracking systems are known for adjusting the angle of solar panels depending on the sun's position. A typical single axis rotation system is, however, highly mechanical and subject to continuous adjustment and maintenance. Offset against this inconvenience is the fact that having an efficient system with the benefits of daily and seasonal tracking of the sun can increase the energy output of a photovoltaic by an estimated factor of three to four times over flat, fixed photovoltaic panels. The solar covering of the present embodiments can remove the need to provide tracking in conventional solar panels.

However, when smaller high efficiency photovoltaics are used, such as the photovoltaic chips described with reference to FIG. 5, a tracking mechanism may be used that slides the photovoltaic back and forth under the solar covering to track the solar “sweet spot” throughout the day. This may be provided in particular in larger commercial installations.

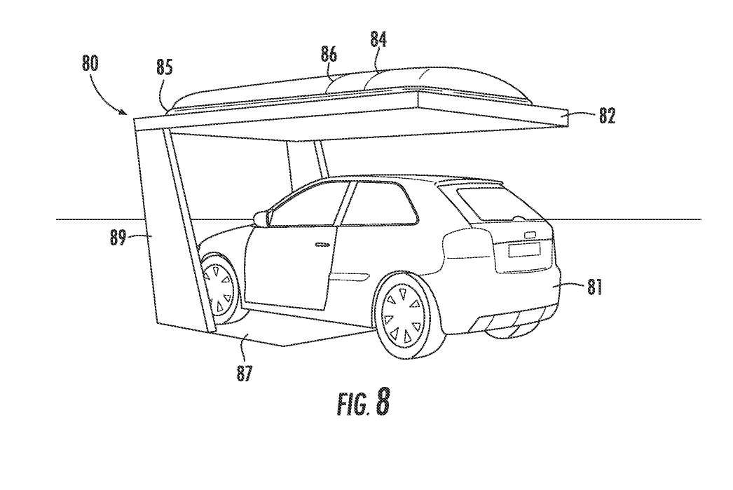

Each of the lenses in the fixed lens array can concentrate light into an engineered narrow angle providing a concentration zone. This focus of light can be tuned to an increased light concentration that lends itself to utilize high efficiency photovoltaic material, such as multi junction photovoltaic cells that can convert a higher amount of sunlight into electricity. FIG. 6 shows the function of sunlight 61 being concentrated 63, through a Fresnel lens 61, onto a high efficient PV cell 64. High efficiency photovoltaic materials are generally capable of providing greater than 30% efficiency at converting the suns light into electricity. A high efficiency photovoltaic material may include a single junction, double junction, and triple junction solar cell material. A smaller focal point may move slightly under each fixed Fresnel lens. To optimize the high efficiency photovoltaic material, small solar cells can be mechanically moved under the fixed canopy of the Fresnel lens web to best capture the concentrated sunlight. A tuning device 70 shown in FIG. 7 may include a frame 71, with guide rails 72. In one embodiment, the guide rails may be provided on the inner framework 52 of the solar canopy of FIG. 5. A photovoltaic (PV) element 73, is fixed to a base 74, that may also serve as a heat sink to provide passive cooling. The PV base 74, has a linear tooth rail 75, on the side that is used to ratchet movement in small measured increments. The linear tooth rail 75, is mechanically moved by an actuator 76, that is attached to a wire 77 which in turn is fixed to a ratchet head 78, and spring loaded 79, to ensure the ratchet head 78, moves to the next tooth up on the linear tooth rail 75. In this simple mechanical device, the PV element 73, can be moved to remain in the point of concentrated light to ensure optimal electrical production. Depending on the application, the size of the photovoltaic and the type of lens used (e.g. imaging lens, Fresnel lens, etc), the lens may be required to move by large distances, such as 15 inches down to less than an inch. The actuator 76, can be controlled by a simple timer that is synchronized with the daily cycle of the sun. Control of a mechanical device may be accomplished by an embedded controller or other computing system that can use time, a light sensor, or current output from the PV element as a schedule to move the PV element 73. There are a number of mechanical means that can be employed to accomplish the movement of the PV element 73, such as using any linear motion driven by a force exerted in measured increments. A further alternative is the use of threaded worm drives that provide incremental and controlled movement.

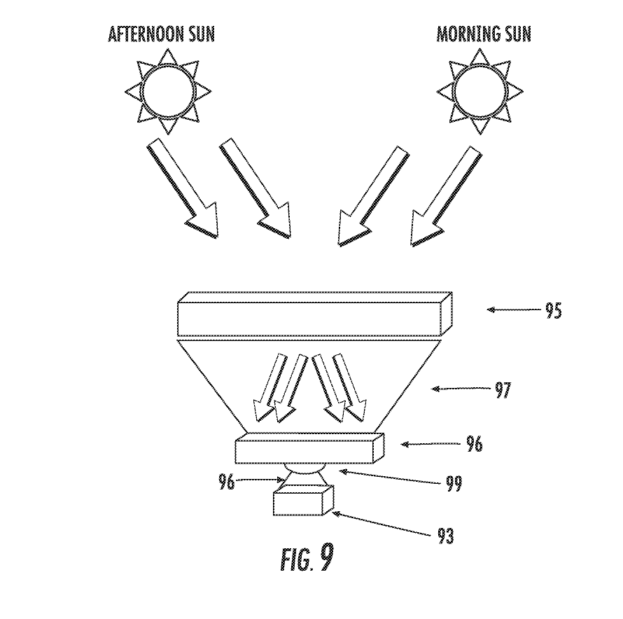

The solar covering of the type described above may be provided in many different types of installations. One particular installation, depicted in FIG. 8 is a solar cabana 80 providing shelter for a car 81 or similar vehicle. The cabana may have a framework 89 that supports a roof 82. A platform 87 may be provided as a base. The roof 82 of the cabana 80 may include an arch support structure 84 that supports a lens array 86 as described previously. A photovoltaic panel 85 or other solar absorber may be disposed on the roof 82 beneath the lens assembly.

The support structure 84, lens array 86 and photovoltaics 85 may be provided as a modular unit. The framework 89 may be constructed from any suitable material including wood, metal and plastics. The framework 89 may be pre-fabricated and provided in a kit form that allows easy purchase and construction by a consumer following a set of instructions that may be provided with the kit.

The framework 89 may be hollow or solid. Where the framework is hollow, a door, hatch or similar opening (not shown) may be provided to an internal compartment that can be used to store batteries, control components and other circuitry for use with the solar covering.

As an example, lithium ion batteries are small enough to be stored in the support columns 89 of the solar cabana 80. For roof mounted domes, batteries can be in columns next to a structure such as a house or garage structure, or other building.

The ability to move the high efficient photovoltaic cells in and out of the concentration zones of the lens elements of the solar coverings enables the capacity to tune the power output to meet specific electrical needs. For example, a large installation of solar panels typically has no control over the output of electricity, with the output being dependent on the sun and weather. The current power grid must constantly adjust the power output to meet demand. If there is too little power then the consumers on the grid may experience a brown out (not enough electricity). Too much power can lead to circuits being overloaded. The ability to move the PV cells 73 (FIG. 7) enables the rapid tuning of electricity to changing demands. A photovoltaic system that can rapidly be tuned to meet demand can provide a stabilizing effect to the power grid.

Each lens element of the solar covering of FIG. 1, 2 or 3 may be designed to provide sunlight to a particular concentration zone. Beneath the solar covering, one or more high efficiency PV elements may be provided for each concentration zone, as shown in FIG. 5. In one embodiment, multiple PV elements 73 (FIG. 7) may be provided on a single set of guide rails 72 allowing multiple PV elements to be moved by a single actuator 76. The actuator 76 can move the elements into and out of their respective concentration zones thereby allowing significant tuning of the PV cells beneath the solar covering. For example, a row of PV cells may be brought on line when power demands dictate.

Because each lens element can capture light from a wide incident angle and focus the light into a receiving zone, the central point of each receiving zone will move only slightly with changes in the incident angle of the sunlight. Therefore, the tuning mechanism described herein is required to provide only relatively small movements, which can be achieved with minimal energy input, compared to the large angle changes required by prior art tracking systems mentioned previously. The energy advantage is further increased where high efficiency photovoltaics are used because the smaller and lighter photovoltaic systems can be moved with reduced energy requirements.

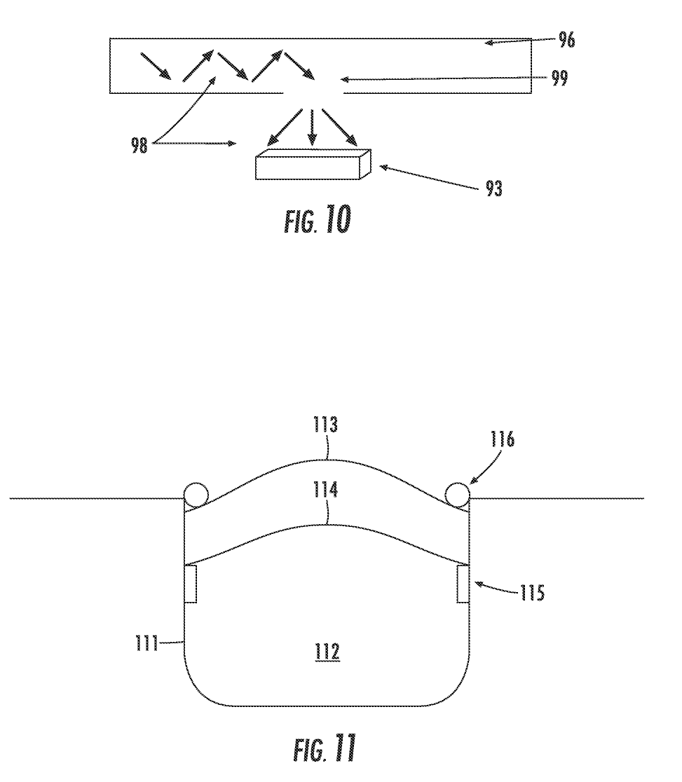

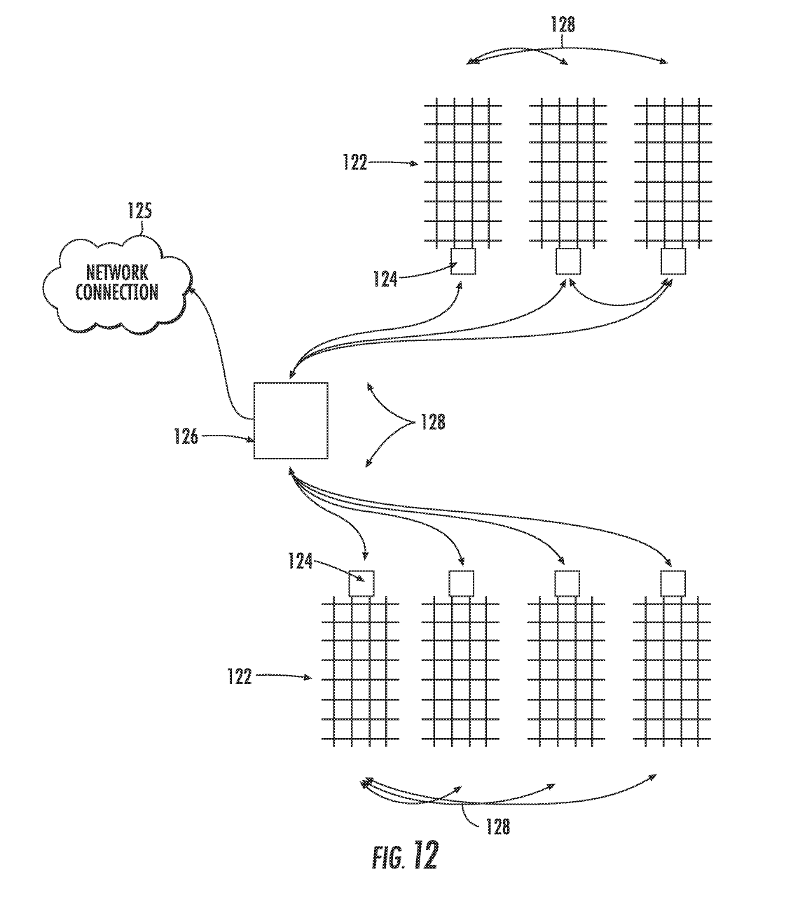

As an alternative or an additional means for moving the high efficiency photovoltaic material mechanically, concentrated light can be channeled through the use of holographic material that may or may not employ a mechanical means. FIG. 9 shows a fixed Fresnel lens 95 providing sunlight to a high efficiency PV 93 via a holographic material 96. Daily sunlight passes through a fixed Fresnel lens 95 from morning through afternoon. As the sun moves, the area of concentrated sunlight 97 will move along holographic material 96. As is shown in FIG. 10, concentrated sunlight 98, is refracted within the holographic material 96, until it passes through an optical guiding lens 99, that guides the concentrated sunlight 98, onto the photovoltaic cell 93. The holographic material 96 enables a concentrated sunlight 98, to be tracked without the use of any mechanical device.

Providing the solar covering over the solar receiving elements can also allow light of frequencies not picked up by the photovoltaic panels to be captured as heat by water, oil, or molten salt, or other solar absorbers. A cross-sectional view of one embodiment is shown in FIG. 11 in which a tube 111 holding water 112 or other liquid is covered by a lens array 113 as described above. An optional photovoltaic panel 114 may be disposed on supports such as a shelf 115 under the lens array 113 and over the surface of the water 112 or other liquid. In one embodiment, the water 112 may be collected from collection tubes 116. In an alternative embodiment, the water 112 may be circulated through a hot water system of a premises.

In one particular embodiment a canopy for use on an automobile shelter may have dimensions of about 5 feet by about 12 feet with an arc radius of the support structure in the shorter side of about 18 inches high. An example size for the circular lens elements may be four inches on a side up to about 18 inches. However other sizes may be found to be suitable depending on the size of the collector and absorber. A person skilled in the art will realize that these dimensions may be scaled and altered appropriately to accommodate the dimension of any particular embodiment and application as a matter of design choice.

In one embodiment, a drive in cabana having a solar covering canopy may be provided with a flat plate in the platform 87 (see FIG. 8) that will rise under the vehicle engine of an electric or hybrid vehicle to inductively transfer energy to charge the DC batteries of the vehicle. The rectifier of the pluggable hybrid will convert the AC current from the inductive charger back into DC current.

According to another aspect of the invention, the cabana of FIG. 8 may be associated with a computer or computer network. In one embodiment, the computer network may be used to store the history of the usage of the vehicle housed within the cabana and, thru GPS onboard functions, will know the locations of the vehicles at any moment in time.

For short trips, the two main sources of wasted energy are cold engine starts and low tire pressures. The expected network signature of the travel patterns of the vehicles will allow the system to predict when to expect the vehicles to travel. Based on this signature and observed history the induction charging plate may employ onboard air vents to preheat the engine. The system may also be able to monitor parameters such as tire pressure and issue an indication of low pressure tires.

The computer system may include multiple wireless connections that allow the system to link to the security and surveillance systems of a building as well as the building HVAC and entertainment systems. Such links may be implemented using technology such as Apple iPhone, a likely control for these system interactions that is already being used by selected manufacturers.

The present invention may have the capability of providing emergency electricity for an associated building during power outages. This will prevent communications failures, internet outages, and guarantee emergency lighting. Building surveillance systems can also continue to function. Medium sized solar cabana systems can maintain heating, cooling, refrigeration and lighting for reasonable periods during power failures at night. Daylight will refresh the system power even during power outages.

Furthermore, the DC electricity from the solar cabana batteries may be supplied to solar circuit breakers in the circuit panel of an associated building such as a home. The DC circuit breaker may contain an inverter circuit that can supply 20 amp 120 volts at 60 cycles to the home system. The breaker will fail over to power company power if the battery system is depleted. This will transfer all 120 volt AC devices on that circuit breaker to the DC back-up system when the DC system activates the breaker.

In one embodiment, the network may include loosely coupled self sensing and self healing standard network frameworks, such as Zigbee, BlueTooth, or Dynastream's ANT. FIG. 12 shows a diagram of a loosely coupled self sensing network 120 integrated with fixed lens arrays 122. Each fixed lens array 122, utilizes a control structure for managing photovoltaic power operations, such as tracking the small movement of concentrated light under a fixed lens element to optimize or regulate power output from a high efficient PV cell. The installation of many units benefit from network connectivity, through network hardware 124, that employ a standard network protocol and framework such as Zigbee, BlueTooth, or ANT. These network frameworks use wireless connectivity to self identify and register compatible devices within their wireless signal area and can connect with other network hardware devices in the event one fails to create a self healing network. Network connectivity enables the fixed lens array 122, to communicate through the network to outside points as well as each other. Network connectivity enables the performance monitoring and control of each fixed lens array 122. Should one fixed lens array fail, performance monitoring can show which unit failed and potentially why. Network connectivity also enables monitoring of system health and performance from a remote location. Each Zigbee enabled network hardware device 124, can communicate with the others as well as a connectivity gateway 126, that serves as a connection to other networks 125, such as the Internet or an Intranet. The use of wireless connections 128 by the network hardware 124 eliminates the requirement for costly wiring and simplifies installation. Zigbee is a specification that uses communication protocols IEEE 802.15.4-2003 standard for wireless networks. Other network technologies types can be used, such as personal area networks, local area networks, campus area networks, metropolitan area networks, wide area networks, global area networks or virtual private networks.

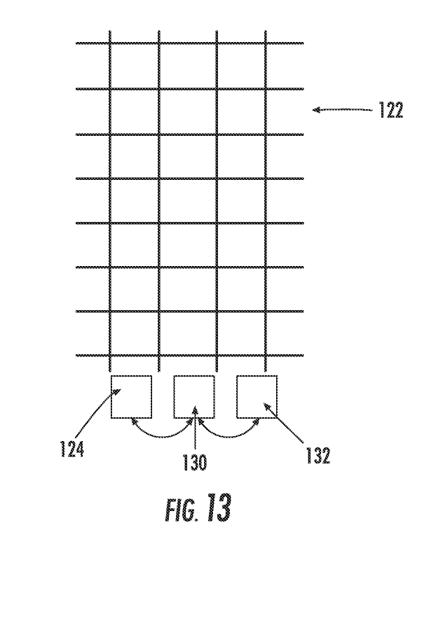

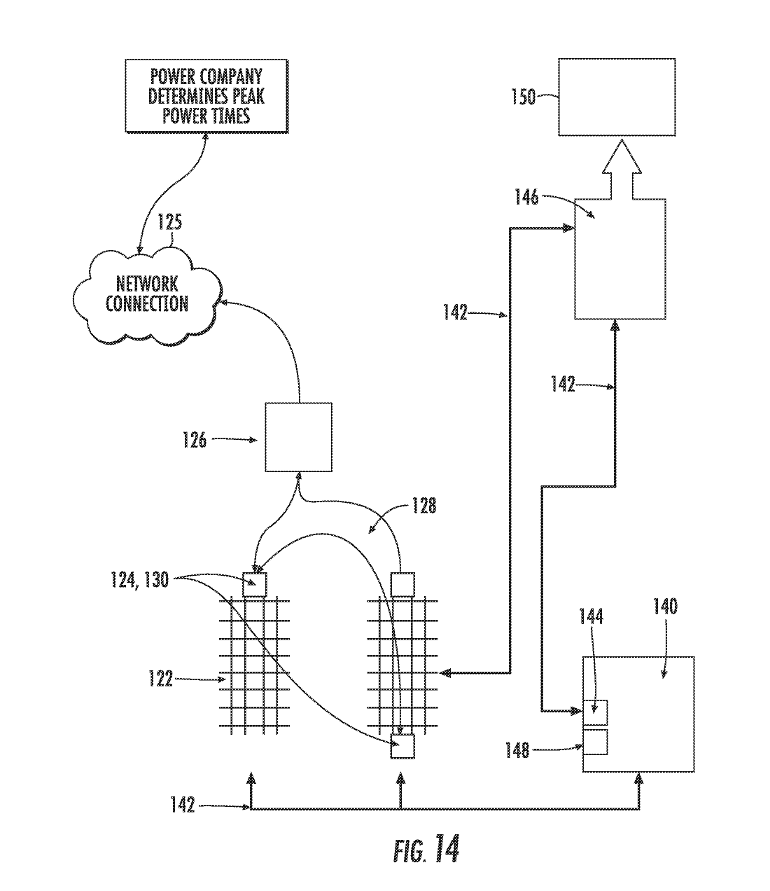

The fixed lens array can be used to collect a wide range of information through the deployment of sensors. For example, a weather sensor may be attached and used for collecting and storing actionable data. A range of other sensors may be added to serve specific functions, such as a global positioning system (GPS) on a mobile solar power battery backup unit. FIG. 13 shows how a sensor 132, may integrate with a fixed lens array 122. Each fixed lens array 122 may contain one or more control systems 130 that is responsible for functions such as monitoring power output, controlling the movement of PV cells, generating historical data through data logging, and regulating battery storage. The network hardware 124, enables communication to outside networks, such as the Internet or Intranet as described above. This network connectivity can be used to send a range of information from the fixed lens array 122. Functions directly beneficial to the fixed lens array 122, can be utilized directly by the control system 130 in managing the fixed lens array 122. The control system can benefit from weather data, either gathered through local sensors or provided through the network hardware 124, to aid in power output prediction and control. Solar power production can benefit from measuring power output through sensors such as temperature, humidity, light, smoke, weight, rain gauge, air speed indicator, ammeter, current sensor, galvanometer, multimeter, ohmmeter, voltmeter, watt-hour meter, and photometer. Each of these sensors can provide information to the control system to monitor the health and performance of the fixed Fresnel lens array 122. Gathering historical data from sensors enables predictive models for performance to be implemented by the control system 130. Other sensors can be implemented on the fixed Fresnel lens array 122, that benefit the geographical location. For example, a fixed Fresnel lens array that is on top of a car charger can be deployed with a proximity sensor and a video camera for security reasons integrated into the control system 130. Scientific study in remote locations, such as the study of earthquakes and volcanoes, can benefit from a solar powered instrument pack that may include magnetic field, gravity, vibration, sound, environmental molecule, biomolecular, biosensor, gas detector, pyranometer, seismometer, lab on a chip, carbon dioxide sensor, and/or chemical field-effect transistor sensors integrated into the control system that can relay data through the network hardware 124. Military operations utilizing solar power in remote locations can benefit from a fixed Fresnel lens array with mission specific functional sensors to detect chemical or biological agents using sensors such as environmental molecule, biomolecular, biosensor, gas detector, pyranometer, seismometer, lab on a chip, and chemical field-effect sensors.

When a computer and storage are coupled with the fixed lens web and a battery, sensors such as current or voltage can detect a power outage and immediately provide electricity from the battery. FIG. 14 illustrates the time shifting of electrical power using a fixed lens array 122 coupled with a battery 140. The fixed lens array 122 provides power through power line 142, to the battery 140. The fixed lens array 122, can also provide power through power line 142, to power grid interconnectivity 146, that can then provide power to a local resource or send power back into the grid to the connected utility company. Utilizing sensors such as current detection, the network hardware 124 and system controller 130 can communicate with the battery control 144 through the battery network hardware 148, in order to release power from the battery 140 onto the power line 142 to the power grid interconnectivity 146, in the event of a connection disruption to the power grid 150 connection. In addition to providing power in the event of a connection disruption to the power grid 150, external sources, such as the local utility company, can send commands via wireless connections 128 through the connectivity gateway 126 to the network hardware and system controller 124/130 to release power from the battery 140, onto the power grid during peak times of power need. The battery can be discharged during peak power time in order to maximize the value of the solar generated power. When the system controller has access to sources of information, such as the local utility company or power monitoring board, battery power can be provided before a blackout occurs. Internal sensors as well as external sources of information enable the onboard computer to make predictions as to when to discharge batteries. Internal and external sources of information may also allow the onboard computer to be actionable, such as proactively discharging batteries during peak hours of energy consumption.

While the embodiments have been described with particular reference to Fresnel lenses, other lens types may be used in the lens array that are suitable for capturing sunlight from a relatively broad angle and redistributing the sunlight onto a receiving element beneath the lens array.

Similarly, while the embodiments have been described with particular reference to the use of photovoltaics as the receiving element, and in particular to photovoltaic chips, other types of receiving elements may be utilized including any suitable photovoltaic cell or non-electrical solar absorbers.

Although the description above contains many specifications, these should not be construed as limiting the scope of the invention but as merely providing illustrations of some of the embodiments of this invention. Thus, the scope of the invention should be determined by the appended claims and their legal equivalents rather than by the examples given.

What is claimed is:

1. A solar panel cover comprising:
(A) a support structure;
(B) a plurality of lens elements supported by the support structure; and
(C) wherein the plurality of lens elements are configured to distribute light incident upon the cover to at least one solar receiving element disposed beneath the cover.

2. The solar panel cover of claim 1 comprising a covering over the support structure, the covering comprising the plurality of lens elements.

3. The solar panel cover of claim 2 wherein the plurality of lens elements comprise a plurality of Fresnel lens ribs.

4. The solar panel cover of claim 3 where one or more of the Fresnel lens ribs comprises an interconnect structure that allows multiple Fresnel lens ribs to be joined.

5. The solar panel cover of claim 2 wherein the plurality of lens elements comprise a plurality of lens elements embossed in the covering.

6. The solar panel cover of claim 2 wherein the plurality of lens elements comprise a plurality of lens tiles.

7. The solar panel cover of claim 6 wherein the plurality of lens elements comprise a plurality of Fresnel lenses.

8. The solar panel cover of claim 2 wherein the covering comprises a continuous plastic sheet.

9. The solar panel cover of claim 1 comprising one or more holographic elements configured to receive light from the plurality of lens elements and to direct the light to one or more solar receiving elements disposed beneath the cover.

10. The solar panel cover of claim 1 configured to be installed over an existing photovoltaic system.

11. The solar panel cover of claim 1 wherein the support structure, the lens elements and the solar receiving element are stationary and the lens elements are configured to focus sun light on the solar receiving elements as the sun changes position relative to the cover.

12. A solar collector system comprising:
(A) one or more solar receiving objects;
(B) a cover supported over the one or more solar receiving objects and comprising one or more lens elements; Reviewand
(C) wherein the plurality of lens elements are configured to distribute light incident upon the cover to the one or more solar receiving elements.

13. The solar collector system of claim 12 wherein the one or more lens elements provide one or more concentration zones beneath the covering and wherein the one or more solar receiving objects are disposed in the one or more concentration zones.

14. The solar collector system of claim 13 comprising at least one tuning mechanism configured to adjust the position of at least one of the solar receiving objects relative to at least one concentration zone.

15. The solar collector system of claim 14 wherein the tuning mechanism is configured to maintain the at least one solar receiving object within the at least one concentration zone.

16. The solar collector system of claim 14 wherein the tuning mechanism comprises:
(A) at least one guide rail;
(B) a base mounted on the at least one guide rail and supporting at least one of the solar receiving objects; and
(C) an actuator for causing movement of the base along the at least one guide rail.

17. The solar collector system of claim 16 wherein the at least one solar receiving object comprises a photovoltaic chip.

18. The solar collector system of claim 17 wherein the actuator controls the movement of a plurality of photovoltaic chips.

19. The solar collector system of claim 16 wherein the base is configured to provide passive cooling to a solar receiving object supported on the base.

20. The solar collector system of claim 14 wherein the tuning mechanism is configured to receive an external signal and to move the at least one solar receiving object into or out of the at least one concentration zone in response to the external signal.

21. The solar collector system of claim 20 configured to receive the external signal from a power company.

22. The solar collector system of claim 12 wherein the one or more solar receiving objects comprise one or more photovoltaic elements.

23. The solar collector system of claim 22 wherein the one or more solar receiving objects comprise one or more heat absorbing elements configured to absorb solar radiation that is not absorbed by the one or more photovoltaic elements.

24. The solar collector system of claim 12 comprising one or more holographic elements configured to receive light from the one or more lens elements and to direct the light to the one or more solar receiving objects.

25. The solar collector system of claim 12 wherein the plurality of lens elements comprise a plurality of Fresnel lenses, each Fresnel lens distributing light into a concentration zone and wherein the plurality of solar receiving objects comprise a plurality of photovoltaic element, each photovoltaic element being associated with one of the concentration zones.

26. A solar cabana comprising:
(A) a framework;
(B) a roof supported by the framework; and
(C) a solar power system supported by the roof, the solar power system comprising:
(a) one or more photovoltaic elements;
(b) a cover supported over the one or more photovoltaic elements; and
(c) one or more lens elements supported by the cover and configured to distribute light incident upon the cover to the one or more photovoltaic elements.

27. The solar cabana of claim 26 wherein the framework is configured to store one or more batteries.

28. A solar cabana kit comprising:
(A) a roof configured to support a solar power system;
(B) a framework configured to support the roof; and
(C) a solar power system comprising:
(a) a solar power system support structure;
(b) a plurality of lens elements configured to be supported on the solar power system support structure; and
(c) one or more photovoltaic elements.
